(19) United States
(12) Patent Application Publication
(10) Pub. No.: US 2025/0316597 A1
(43) Pub. Date: Oct. 9, 2025

(54) BORON-NITRIDE FILM AND SEMICONDUCTOR DEVICE INCLUDING THE SAME

(71) Applicants: Samsung Electronics Co., Ltd., Suwon-si (KR); SEOUL NATIONAL UNIVERSITY R&DB FOUNDATION, Seoul (KR)

(72) Inventors: Taehoon KIM, Suwon-si (KR); Jaewon KIM, Suwon-si (KR); Hyun WOO, Seoul (KR); Van Luan NGUYEN, Suwon-si (KR); Hyejin JANG, Seoul (KR)

(73) Assignees: Samsung Electronics Co., Ltd., Suwon-si (KR); SEOUL NATIONAL UNIVERSITY R&DB FOUNDATION, Seoul (KR)

(21) Appl. No.: 19/016,693

(22) Filed: Jan. 10, 2025

(30) Foreign Application Priority Data
Apr. 8, 2024 (KR) 10-2024-0047364

(51) Int. Cl. H01L 23/532; H10B 43/27

(52) U.S. Cl. CPC H01L 23/5329; H10B 43/27

(57) ABSTRACT

A boron nitride film and a semiconductor device including the boron nitride film are provided. The boron nitride film may include a boron nitride compound h a dielectric constant of about 2.3 or more and about 8 or less at an operating frequency of 100 kHz and have a thermal conductivity of about 1.3 W/mK or more and about 10 W/mK or less.

### CROSS-REFERENCE TO RELATED APPLICATION

This application is based on and claims priority under 35 U.S.C. § 119 to Korean Patent Application No. 10-2024-0047364, filed on Apr. 8, 2024, in the Korean Intellectual Property Office, the disclosure of which is incorporated by reference herein in its entirety.

### BACKGROUND

### 1. Field

The disclosure relates to a boron nitride film having low permittivity and high thermal conductivity and a semiconductor device including the boron nitride film.

### 2. Description of the Related Art

Electronic devices and semiconductor devices are mostly manufactured by combining and connecting semiconductors with insulators and conductors. For example, after forming a plurality of unit devices on a semiconductor substrate, various integrated circuits may be manufactured by repeatedly stacking an insulating layer and an electrode wiring on the plurality of unit devices.

However, in the process of manufacturing or operating such devices, the temperature of constituent layers may increase, and electric stress may occur due to a voltage/current applied to the constituent layers. Accordingly, diffusion of materials (atoms) may occur between adjacent constituent layers, which may lead to degradation of device characteristics and decrease in reliability and durability. When a degree of integration of devices increases, it may become harder to solve the issues caused by the diffusion of material between constituent layers. In addition, even when no diffusion of material occurs, a signal delay may occur due to a mutual interference caused by an electric field between wirings of a device having a high integration degree.

Further, as a degree of integration of integrated circuits increases significantly, a distance between conductor patterns decreases gradually. Accordingly, the parasitic capacitance between the conductor patterns increases, which may lead to performance degradation of electronic apparatuses. For example, the parasitic capacitance may delay a signal transmission of semiconductor devices. To reduce such parasitic capacitance, insulator materials having a relatively low permittivity have been used as an interlayer insulating film. In addition, because the influence of heat between conductor patterns increases, heat dissipation materials are being explored.

### SUMMARY

Provided is a boron nitride film having low permittivity and high thermal conductivity.

Provided is a semiconductor device including a boron nitride film having low permittivity and high thermal conductivity.

Additional aspects will be set forth in part in the description which follows and, in part, will be apparent from the description, or may be learned by practice of the presented embodiments of the disclosure.

According to an aspect of the disclosure, a boron nitride film includes a boron nitride compound, has a dielectric constant within a range of about 2.3 to about 8 at an operating frequency of 100 kHz, and has a thermal conductivity within a range of about 1.3 W/mK to about 10 W/mK.

The thermal conductivity may be in the range of about 1.7 W/mK to about 5 W/mK.

A ratio of boron to nitrogen in the boron nitride film may be in the range of about 1.15 to about 1.5.

The boron nitride film may have at least one of an amorphous structure or a nanocrystal structure.

The boron nitride film may have a thickness in a range of about 1 nm to about 1 μm.

The boron nitride film may have a mass density of about 1 g/cm³ to about 3 g/cm³.

The boron nitride film may have a breakdown field of 4 MVcm⁻¹ or more.

The boron nitride film may have a roughness in a range of about 0.3 root-mean-square (RMS) to about 0.6 RMS.

According to another aspect of the disclosure, a semiconductor device includes a conductive wiring, a dielectric layer surrounding at least a part of the conductive wiring, and a diffusion barrier layer between the conductive wiring and the dielectric layer and configured to inhibit a conductive material of the conductive wiring from diffusing into the dielectric layer, wherein at least one of the dielectric layer and the diffusion barrier layer includes a boron nitride film, and the boron nitride film includes a boron nitride compound, has a dielectric constant within a range of about 2.3 or more and about 8 or less at an operating frequency of 100 kHz, and has a thermal conductivity within a range of about 1.3 W/mK to about 10 W/mK.

According to another aspect of the disclosure, a semiconductor device includes a stack including alternating gate electrodes and boron nitride films; and a plurality of cell strings in the stack, wherein each of the plurality of cell strings includes a channel layer, a charge tunneling layer provided in the channel layer, a charge trap layer provided in the charge tunneling layer, a charge blocking layer provided in the charge trap layer, a gate electrode provided in the charge blocking layer, and a boron nitride film provided in the gate electrode, the gate electrode and the boron nitride film are alternately stacked, and the boron nitride film includes a boron nitride compound, has a dielectric constant in a range of about 2.3 to about 8 at an operating frequency of 100 kHz, and a thermal conductivity in a range of about 1.3 W/mK to about 10 W/mK.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a boron nitride film according to at least one embodiment;

FIGS. 2A to 2C are diagrams illustrating a method of manufacturing a boron nitride film according to at least one embodiment;

FIG. 3 is a diagram schematically illustrating an electronic device including a wiring structure according to at least one embodiment;

FIG. 4 is a diagram illustrating a multilayer structure including a diffusion barrier layer according to at least one embodiment;

FIG. 5 is a diagram illustrating a multilayer structure including a diffusion barrier layer according to another embodiment;

FIG. 6 is a diagram illustrating a transistor including a boron nitride film according to at least one embodiment;

FIG. 7 is a diagram illustrating a semiconductor device including a wiring structure according to at least one embodiment;

FIG. 8 is a diagram illustrating a field effect transistor including a boron nitride film according to at least one embodiment;

FIG. 9 is a diagram illustrating a vertical field effect transistor including a boron nitride film according to at least one embodiment;

FIG. 10 is a diagram illustrating a fin type transistor including a boron nitride film according to at least one embodiment;

FIG. 11A is a view illustrating a part of a display apparatus including boron nitride according to at least one embodiment;

FIG. 11B is a cross-sectional view taken along lines A-A′ and B-B′ of FIG. 11A;

FIG. 12 is a diagram illustrating a NAND flash memory device including a boron nitride film according to at least one embodiment;

FIG. 13 is a cross-sectional view taken along line A-A′ of FIG. 12;

FIG. 14 is an enlarged view of part A of FIG. 13; and

FIG. 15 is a schematic of an electronic device according to at least one embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a boron nitride film and a semiconductor device including the boron nitride film according to various embodiments are described in detail with reference to the accompanying drawings. In the drawings, like reference numerals in the drawings denote like elements, and sizes of components in the drawings may be exaggerated for clarity and convenience of explanation. While such terms as “first,” “second,” etc., may be used to describe various components, such components must not be limited to the above terms. The above terms are used only to distinguish one component from another.

An expression used in the singular encompasses the expression of the plural, unless it has a clearly different meaning in the context. When a portion “includes” an element, another element may be further included, rather than excluding the existence of the other element, unless otherwise described. Sizes or thicknesses of components in the drawings may be arbitrarily exaggerated for convenience of explanation. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, the range of “X” to “Y” includes all values between X and Y, including X and Y. Further, when a certain material layer is described as being disposed on a substrate or another layer, the material layer may be in contact with the other layer, or there may be a third layer between the material layer and the other layer. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. In the following embodiments, materials constituting each layer are provided merely as an example, and other materials may also be used.

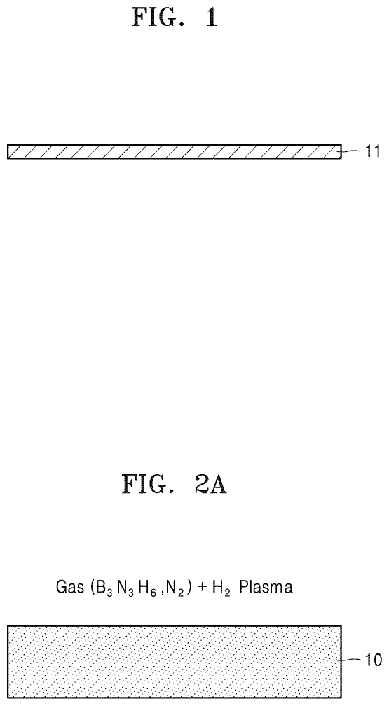

FIG. 1 is a cross-sectional view of a boron nitride film 11 according to at least one embodiment.

The boron nitride film 11 may include a boron nitride compound, have a relatively low dielectric constant, and be configured to have a relatively high thermal conductivity. For example, the boron nitride film 11 may have a dielectric constant in the range of about 2.3 to about 8 at an operating frequency of 100 kHz. In at least some examples, the boron nitride film 11 may have a dielectric constant in the range of about 2.3 to about 5 at an operating frequency of 100 kHz. Additionally, the boron nitride film 11 may be configured to have a thermal conductivity in the range of about 1.3 watts per meter*Kelvin (W/mK) or more and/or about 10 W/mK or less. The boron nitride film 11 may be configured to have a thermal conductivity in the range of about 1.5 W/mK to about 8 W/mK. The boron nitride film 11 may be configured to have a thermal conductivity in the range of about 1.7 W/mK to about 5 W/mK or less.

The boron nitride film 11 may be configured to have a low dielectric constant and a high thermal conductivity and applied to spacers, dielectric layers, diffusion barrier layers, molds, etc. of various types of semiconductor devices. Due to the downscaling of semiconductor devices, spaces between components of semiconductor devices are reduced, and sizes of the components decrease, which may cause diffusion of atoms to occur between adjacent configuration layers or characteristics of semiconductor devices to deteriorate due to generation of heat. Such deterioration characteristics may be improved (e.g., mitigated and/or prevented) by the boron nitride film 11 having a low dielectric constant and a high thermal conductivity.

The boron nitride film 11 may have an amorphous structure or a nanocrystal structure.

Hereinafter, a crystalline boron nitride film, a nanocrystalline boron nitride film (nc-BN), and an amorphous boron nitride film (a-BN) will be described.

The crystalline boron nitride film refers to a boron nitride film including crystal grains with a size larger than approximately 100 nm. The crystalline boron nitride film may include, for example, a hexagonal boron nitride film (h-BN) and/or a cubic boron nitride film (c-BN).

The nc-BN refers to a boron nitride film including crystal grains smaller than those of the crystalline boron nitride film. The nc-BN may include crystal grains with a size of approximately 100 nm or less. For example, the nc-BN may include crystal grains with a size of about 0.5 nm to about 100 nm.

The a-BN refers to a boron nitride film including the amorphous structure. The a-BN may include sp³ hybrid bonds and sp² hybrid bonds, where a proportion of sp³ hybrid bonds may be less than 20%. Meanwhile, the a-BN may include a small amount of crystal grains with a size of several nm (e.g., approximately 3 nm or less).

The a-BN may include hydrogen, but the content of hydrogen may be small. For example, the content of hydrogen may be less than approximately 10 atomic percent (at %). The content of hydrogen in the a-BN may be small, and thus, the a-BN may be chemically stable.

The a-BN may have a low refractive index. For example, the refractive index of the a-BN may be about 1.0 to about 1.5 with respect to light in a wavelength range of about 100 nm to about 1000 nm.

The a-BN may have a high density. For example, the density of the a-BN may be approximately 1.8 g/cm³ or more. For example, the density of the a-BN may be about 1 gram per cubic centimeter (g/cm³) to 3 g/cm³ and/or about 1.8 g/cm³ to about 2.5 g/cm³. As described above, the a-BN may have a high density, and thus, the a-BN may have excellent mechanical characteristics.

An energy band gap of the a-BN may be approximately 6.0 eV or less. In addition, a surface roughness of the a-BN may be 0.5 root-mean-square (rms) or less.

The boron nitride film 11 according to at least one embodiment has the amorphous structure or the nanocrystal structure, and accordingly may have the characteristics described above.

Meanwhile, the boron nitride film 11 includes nitrogen (N) and boron (B).

A table 1 below shows results of measuring the dielectric constant and the thermal conductivity while changing a ratio (B/N) of boron (B) to nitrogen (N) in the boron nitride film 11.

TABLE 1

| | | | Thermal conductivity |
|---|---|---|---|
| | B/N ratio | Dielectric constant | (W/mK) |
| Comparative | 1.14 | 2.2 | 1.1 |
| Example | | | |
| Embodiment 1 | 1.24 | 2.85 | 1.75 |
| Embodiment 2 | 1.27 | 4.14 | 1.9 |

Comparative Example shows a case where the B/N ratio is 1.14, Embodiment 1 shows a case where the B/N ratio is 1.24, and Embodiment 2 shows a case where the B/N ratio is 1.27. The thermal conductivity of the boron nitride film 11 was measured through time-domain thermoreflectance evaluation. Referring to Table 1, when the B/N ratio increases, the dielectric constant tends to increase, and the thermal conductivity also tends to increase. For the heat dissipation performance of the boron nitride film 11, a high thermal conductivity may be better, but when the dielectric constant also increases, parasitic capacitance may increase. Accordingly, the boron nitride film 11 according to at least one embodiment may be configured to have a relatively low dielectric constant and a relatively high thermal conductivity. For example, the boron nitride film 11 may be configured to have a thermal conductivity of about 1.3 W/mK to about 10 W/mK. The boron nitride film 11 may be configured to have a thermal conductivity of about 1.7 W/mK to about 5 W/mK or less. The boron nitride film 11 may be configured to have a dielectric constant of about 2.3 to about 8. The boron nitride film 11 may be configured to have a dielectric constant of about 2.3 to about 5 or less. The boron nitride film 11 may have a high stability. For example, the boron nitride film may have a breakdown field of 4 MVcm⁻¹ or more.

In addition, the boron nitride film 11 may be relatively smooth. For example, a surface roughness of the boron nitride film 11 may be about 0.3 rms to about 0.6 RMS based on, e.g., the amount of a-BN. The ratio (B/N) of boron (B) to nitrogen (N) in the boron nitride film 11 may be about 1.15 to about 1.5. For example, the ratio (B/N) of boron (B) to nitrogen (N) in the boron nitride film 11 may be about 1.15 to about 1.3.

As described above, the boron nitride film 11 may be configured to simultaneously satisfy the relatively low dielectric constant and the relatively high thermal conductivity, and accordingly, the boron nitride film 11 may be applicable to dielectric layers, diffusion barrier layers, spacers, etch prevention layers, molds, etc. of miniaturized semiconductor devices. This will be described below.

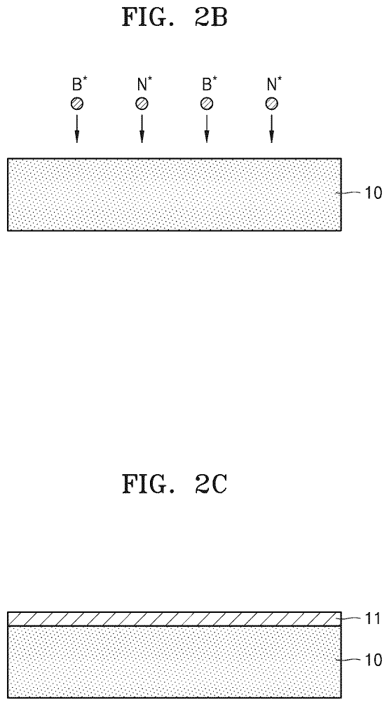

FIGS. 2A to 2C are diagrams schematically illustrating a method of manufacturing the boron nitride film 11 according to at least one embodiment.

Referring to FIG. 2A, a substrate 10 is prepared in a chamber (not shown). FIG. 2A simply illustrates only the substrate 10, but an intermediate structure of an integrated circuit in which the boron nitride film 11 is to be formed may be present on the substrate 10. For example, the substrate 10 may include the intermediate structure for manufacturing various electronic devices such as an image sensor, a display apparatus, a field effect transistor, a solar cell, etc.

Alternatively, the substrate 10 may be a growth substrate for forming the boron nitride film 11. In this case, the substrate 10 may include, for example, at least one of a semiconductor material, an insulating material, and/or a metal material. The semiconductor material may include an elemental (e.g., group IV) semiconductor and/or a compound semiconductor. The group IV semiconductor may include, for example, Si, Ge, or Sn, but is not limited thereto. The compound semiconductor may include, for example, a semiconductor material in which at least two elements of Si, Ge, C, Zn, Cd, Al, Ga, In, B, C, N, P, S, Se, As, Sb, Te, etc. are bonded, a group III-V compound semiconductor, etc. The insulating material may include, for example, at least one of oxide, nitride, and carbide of at least one of Si, Ni, Al, W, Ru, Co, Mn, Ti, Ta, Au, Hf, Zr, Zn, Y, Cr, Cu, Mo, or Gd, or derivatives thereof. Furthermore, the substrate 10 may further include, for example, N and F as a SiCOH-based composition, and may include pores for decrease in permittivity. The substrate 10 may further include a dopant. The materials of the substrate 10 mentioned above are merely examples.

The substrate 10 may be pre-treated before the substrate 10 is disposed in the chamber. For example, the substrate 10 may be immersed in an organic solvent such as acetone, ultrasonicated, and then cleaned with iso-propenyl alcohol (IPA) and nitrogen gas. In addition, native oxides may be removed by immersing the substrate 10 in, e.g., a hydrofluoric acid (HF) solution, and residual HF solution may be removed by using anhydrous ethanol and nitrogen gas.

Also, after the cleansed substrate 10 is prepared in the chamber, carbon impurities remaining on a surface of the substrate 10 may be removed by performing a plasma process on the surface of the substrate 10 in the chamber. For example, the surface of the substrate 10 may be H₂ plasma-processed at about 200° C. to about 800° C. While the surface of the substrate 10 is H₂ plasma-processed, a flow rate of H₂ may be controlled to about 20 standard cubic centimeters (sccm) to about 200 sccm, and plasma power may be maintained at about 20 W to about 100 W and/or about 30 W to about 100 W.

The process temperature for growth of the boron nitride film 11 may be approximately 700° C. or less, which is lower than the temperature used in a chemical vapor deposition process. For example, for growth of the boron nitride film 11 into an amorphous state, the process temperature in the chamber may be about 400° C. Also, before raising the process temperature, the process pressure for the growth of the boron nitride film 11 may be set to be approximately 2 Torr or less. For example, the process pressure may be 10⁻² Torr or less. Alternatively, the process pressure for the growth of a nanocrystalline boron nitride film may be approximately 10 mTorr or higher. For example, the process pressure for the growth of the nanocrystalline boron nitride film may be about 10 mTorr to about 1 Torr.

Then, a reaction gas may be injected into the chamber for the growth of the boron nitride film 11. The reaction gas may be a source for boron nitride for growing the boron nitride film 11 and may be a source including both of nitrogen and boron such as borazine (B₃N₃H₆) and/or ammonia-borane (NH₃—BH₃). Alternatively, the reaction gas may include a nitrogen source including nitrogen and a boron source including boron. The nitrogen source may include at least one of ammonia (NH₃) or nitrogen (N₂), and the boron source may include at least one of BH₃, BF₃, BCl₃, B₂H₆, (CH₃)₃B, or (CH₃CH₂)₃B.

The reaction gas may further include a carrier gas. The carrier gas may further include an inert gas. The inert gas may include, for example, at least one of an argon gas, a neon gas, a nitrogen gas, a helium gas, a krypton gas, and/or a xenon gas. The reaction gas may further include a hydrogen gas. A mixing ratio of the reaction gas injected into the chamber may be modified according to growth conditions of the boron nitride film 11.

The flow rate of the gas for boron nitride may be lower than other those of reaction gases. When the boron nitride film 11 is grown by using plasma, the mixing ratio of the reaction gas injected into the chamber (e.g., a volume ratio between the source for boron nitride and the inert gas) may be, for example, about 1:10 to about 1:5000, For example, a volume ratio among the source boron nitride, the inert gas, and the hydrogen gas may be, for example, about 1:10 to about 1:5000 and/or about 1:10 to about 1:500.

To form an nc-BN, the content of the source for boron nitride in the reaction gas needs to be relatively small, and to this end, the flow rate of the source for boron nitride introduced into the chamber may be relatively low. For example, the flow rate of the source for boron nitride may be selected in a range of about 0.03 sccm to about 1 sccm. For example, during the growth of the boron nitride film 11, the flow rate of the source for boron nitride may be controlled to be 0.05 sccm, and the flow rate of the inert gas may be controlled to be 50 sccm. Also, the flow rate of the hydrogen gas may be controlled to be 20 sccm.

While the reaction gas is introduced into the chamber, the plasma power may be maintained at about 20 W to about 100 W or about 30 W to about 100 W, and the process temperature may be maintained at about 200° C. to about 800° C. A plasma apparatus may be an apparatus providing plasma, including inductively coupled plasma, microwave plasma, capacitively coupled discharge plasma, electron cyclotron resonance plasma, helicon plasma, etc., but the disclosure is not limited thereto. When an electric field is induced in a chamber of the plasma apparatus, plasma for growth of the nc-BN may be generated by the induced electric field.

As the ratio of the source for boron nitride is lower than those of other reaction gases, the crystallinity of boron nitrides may be weakened. Thus, the boron nitride film 11 according to at least one embodiment may be formed in an amorphous or nano-scale crystal structure.

For example, an inductively coupled plasma apparatus may provide a current generated by electromagnetic induction (e.g., a kind of plasma to which energy is supplied by a magnetic field varying over time). When power for generation of plasma is applied to the inside of the chamber from the plasma apparatus, an electric field may be induced inside the chamber. When the electric field is induced while the reaction gas is injected as described above, plasma for growth of the boron nitride film 11 may be formed.

Referring to FIG. 2B, nitrogen (N*) and boron (B*) activated by plasma of the reaction gas obtained by mixing the carbon source, the inert gas, and the hydrogen gas may be generated and adsorbed on the surface of the substrate 10. Then, as the plasma of the inert gas continuously induces the activation of the substrate 10, the adsorption of the activated nitrogen (N*) and the activated boron (B*) on the surface of the substrate 10 may be accelerated. The activated nitrogen (N*) and the activated boron (B*) may be adsorbed amorphously. Even when the activated nitrogen (N*) and the activated boron (B*) are bonded to each other, the amount thereof may be small, and thus, the activated nitrogen (N*) and the activated boron (B*) may be adsorbed as a nano-scale crystal.

Referring to FIG. 2C, as the adsorption of the activated nitrogen (N*) and the activated boron (B*) on the surface of the substrate 10 is accelerated even at a low temperature, the boron nitride film 11 may be grown on the surface of the substrate 10. According to some embodiments, at a low temperature (e.g., at a temperature of 700° C. or less) the boron nitride film 11 is directly grown on the surface of the substrate 10 by the activated boron (B*) and the activated nitrogen (N*) of a low ratio, and thus, the crystallinity of the boron nitride film 11 may be weak.

The boron nitride film 11 according to at least one embodiment may be grown amorphously and/or may be grown in a nano-scale crystal. Even when the amorphously formed boron nitride film 11 has a crystal, the crystal may be 3 nm or less, and the boron nitride film 11 formed in the nano crystal may include crystals with the size of 100 nm or less. The boron nitride film 11 may have an amorphous structure or may include a nanocrystal structure with the size of about 0.5 nm to about 100 nm The boron nitride film 11 may have a thickness of about 1 nm to about 1 μm. Alternatively, the boron nitride film 11 may have a thickness of about 5 nm to about 100 nm. The boron nitride film 11 may have the amorphous structure or the nanocrystal structure, and thus, the boron nitride film 11 may be thin.

After the growth, plasma may be turned off, and a furnace may be slowly cooled down. For example, by injecting H₂ gas of 20 sccm into the chamber, the furnace may be cooled to the room temperature.

A device may be manufactured by forming another layer on the boron nitride film 11 manufactured by using the method described above. Alternatively, the manufactured boron nitride film 11 may be transferred to another layer. A hydrofluoric acid transfer technique may be applied during transfer, but the disclosure is not limited thereto.

Because the boron nitride film 11 manufactured as illustrated in FIGS. 2A to 2C is directly grown from the activated nitrogen (N*) and the activated boron (B*) having a low density at a low temperature, the crystallinity may be low. The lower the at least one of the growth temperature and process pressure may be, the higher the amorphous content may be.

A ratio of nitrogen and a ratio of boron in the boron nitride film 11 may be about 1.1 to about 1.5. In addition, the boron nitride film 11 may include hydrogen, but the amount of hydrogen in the boron nitride film 11 may be small. For example, the content of hydrogen may be 10 at % or less.

The boron nitride film 11 may have a dielectric constant of about 1.15 or more or about 1.5 or less at an operating frequency of about 100 kHz (the dielectric constant may refer to a relative dielectric constant with respect to vacuum or air). Also, the boron nitride film 11 may have a thermal conductivity of about 1.3 or more and about 10 or less W/mK.

The boron nitride film 11 according to at least one embodiment may be applied to various semiconductor devices.

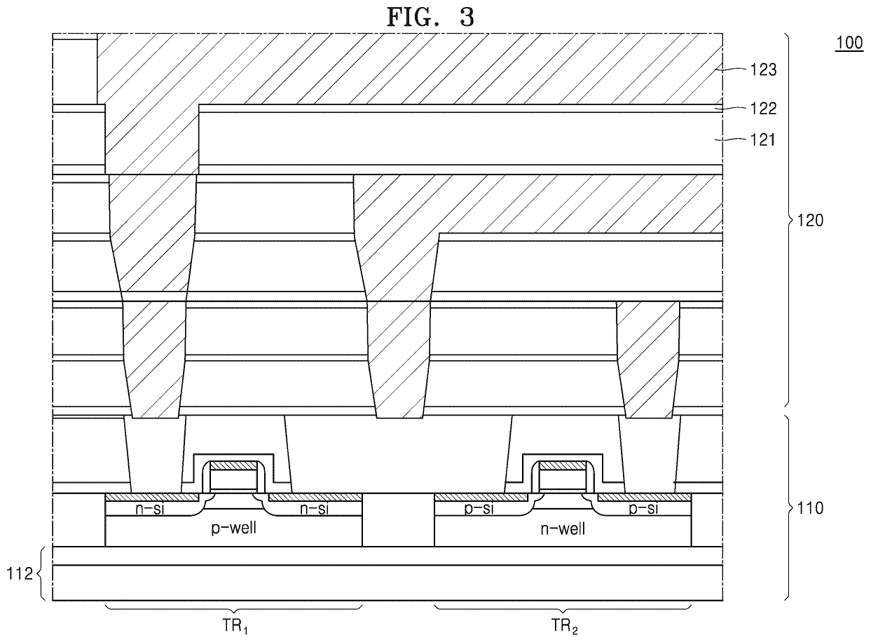

FIG. 3 is a diagram schematically illustrating an electronic device 100 including a wiring structure 120 according to at least one embodiment.

Referring to FIG. 3, the electronic device 100 includes a device layer 110 and the wiring structure 120 that electrically connects the device layer 110.

The device layer 110 may include a substrate 112. For example, the substrate 112 may be a semiconductor substrate, and may include, for example, a group IV semiconductor material, a group III/V semiconductor compound, and/or a group II/VI semiconductor compound. The substrate 112 may include Si, Ge, SiC, SiGe, SiGeC, Ge Alloy, GaAs, InAs, InP, etc. However, this is merely an example, and various other semiconductor materials may be used as the substrate 112.

The substrate 112 may include a single layer or multiple layers in which different materials are stacked. The substrate 112 may include, for example, a silicon-on-insulator (SOI) substrate or a silicon germanium-on-insulator (SGOI) substrate. In addition, the substrate 112 may include a non-doped semiconductor material or a doped semiconductor material.

The device layer 110 may include one or more semiconductor devices (such as resistors, diodes, capacitors, transistors etc.). Two transistors TR₁ and TR₂ are shown in FIG. 3, but the disclosure is not limited thereto. One or more semiconductor devices may be formed by using techniques well known to one of ordinary skill in the art. Thus, the device layer 110 may include at least one of a transistor, a capacitor, a diode, a resistor, etc., and the electronic device 100 may be a system memory, a memory device, a display apparatus, a mobile device, etc.

The wiring structure 120 may be disposed on the device layer 110. The wiring structure 120 may have a structure in which a plurality of metallization layers are stacked. The wiring structure 120 may include a dielectric layer 121, a diffusion barrier layer 122 provided on the dielectric layer 121, and a conductive wiring 123 provided on the diffusion barrier layer 122. The diffusion barrier layer 122 may prevent a metal material of the conductive wiring 123 from diffusing into the dielectric layer 121. At least one of the dielectric layer 121 and/or the diffusion barrier layer 122 may include the boron nitride film 11 according to at least one embodiment. At least one of the dielectric layer 121 and/or the diffusion barrier layer 122 may include at least one of an a-BN and/or an nc-BN.

As described above, the boron nitride film 11 may be used as a component of the wiring structure 120. For example, the boron nitride film 11 may be applied to at least one of a front-end-of-line (FEOL) or a back end of line (BEOL) of the wiring structure 120. The FEOL is a portion of an integrated circuit (IC) in which individual devices (e.g., transistors, capacitors, resistors, etc.) are patterned on a semiconductor substrate or a layer. The FEOL may include metal interconnect layers. After a final FEOL operation, a result may typically be a wafer with isolated transistors (e.g., without any wires). The BEOL is a portion in which individual devices (e.g., transistors, capacitors, resistors, etc.) interconnect with wirings on the wafer, such as a metallization layer or layers. The BEOL may include contacts, insulating layers (dielectrics), metal levels, and bonding sites for chip-to-package connections. In the BEOL of manufacturing stage contacts (pads), interconnect wires, vias and dielectric structures may be formed. In recent IC processes, more than 10 metal layers may be added in the BEOL.

The conductive wiring 123 may include metal and/or metal alloy with excellent electrical conductivity. For example, the conductive wiring 123 may include Cu, Ru, Al, Co, W, Mo, Ti, Ta, Ni, Pt, Cr, Rh, Ir, etc., and/or alloys thereof. However, the disclosure is not limited thereto, and various other metals may be used as the conductive wiring 123. The diffusion barrier layer 122 may have a thickness of about 1 nm to about 1 μm. In addition, the dielectric layer 121, the diffusion barrier layer 122, and the conductive wiring 123 may be formed at a low temperature, and thus, the electronic device 100 is easily manufactured.

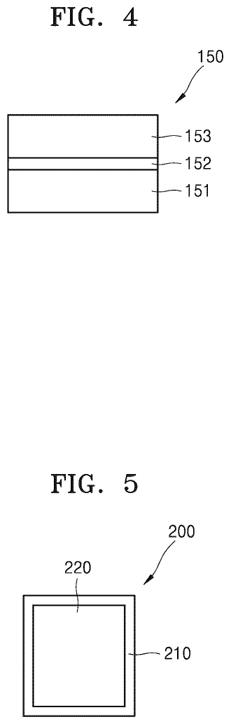

FIG. 4 is a diagram illustrating a multilayer structure 150 including a diffusion barrier layer 152 according to at least one embodiment. As shown in FIG. 4, the multilayer structure 150 may include a first material layer 151, a second material layer 153 spaced apart from the first material layer 151, and the diffusion barrier layer 152 provided therebetween.

The first material layer 151 and the second material layer 153 may include different materials. The diffusion barrier layer 152 may serve to suppress and/or prevent the movement (diffusion) of atoms between the first material layer 151 and the second material layer 153. The diffusion barrier layer 152 may include the boron nitride film 11 described above. In addition, the diffusion barrier layer 152 may further include a material other than the boron nitride film 11 according to at least one embodiment. In at least one embodiment, the diffusion barrier layer 152 may also include a metal chalcogenide-based material with a two-dimensional (2D) crystal structure and graphene. Alternatively, the diffusion barrier layer 152 may also include Ti, Ta, TiN, TaN, TiSiN, WC, Co, MnN, Mn, metal silicide, etc. One of the first material layer 151 and the second material layer 153 in FIG. 4 may be a conductive material, and the other may be a semiconductor material. Alternatively, one of the first material layer 151 and the second material layer 153 may be a conductive material, and the other may be an insulating material.

For example, the first material layer 151 may be an insulating layer, and the second material layer 153 may be a conductive layer. The first material layer 151 may include silicon oxide, silicon nitride, silicon nitride, etc., and/or may be an insulating layer including a high dielectric material with a higher dielectric constant than silicon nitride. Alternatively, the first material layer 151 may include a SiCOH-based organic-inorganic hybrid organic insulating material. Any insulating material used in general electronic devices or semiconductor devices may be applied to the first material layer 151. The second material layer 153 may be a metal layer or a metal compound layer. In this case, the diffusion barrier layer 152 may serve to suppress and/or prevent the material of the second material layer 153, for example, metal atoms, from moving/diffusion into the first material layer 151.

FIG. 5 is a diagram illustrating a multilayer structure 200 including a diffusion barrier layer 210 according to another embodiment.

Referring to FIG. 5, the diffusion barrier layer 210 may be provided to cover at least one surface of a conductive layer 220. For example, the diffusion barrier layer 210 may be provided to cover the entire side surface of the conductive layer 220. The conductive layer 220 may be a layer including metal and/or a metal compound (e.g., an alloy, a nitride, and/or an oxide). The diffusion barrier layer 210 may include the boron nitride film 11 according to at least one embodiment. Although not shown in FIG. 5, another material layer bonded to the conductive layer 220 with the diffusion barrier layer 210 therebetween may be further provided. The other material layer may be a semiconductor layer or an insulating layer. In addition, a predetermined adhesive layer may be further provided between the diffusion barrier layer 210 and the conductive layer 220. Although not shown in FIG. 5, the diffusion barrier layer 210 may be provided to cover the entire side surface of a conductive material layer.

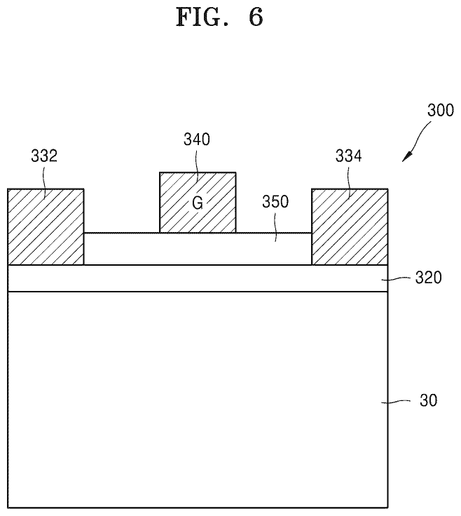

FIG. 6 is a diagram illustrating a transistor 300 including the boron nitride film 11 according to at least one embodiment.

Referring to FIG. 6, the transistor 300 includes a substrate 310, a channel 320 provided on the substrate 310, a source 332 and a drain 334 provided to apply a voltage to the channel 320 and spaced apart from each other, a gate 340 provided to form an electric field in the channel 320, and a gate insulating layer 350 provided between the channel 320 and the gate 340.

The substrate 310 may include a material such as silicon (Si), silicon-germanium, silicon carbide (SiC), glass, plastic, and/or the like. In addition, the substrate 310 may include an epitaxial layer, a silicon-on-insulator (SOI) layer, a semiconductor-on-insulator (SEOI) layer, etc.

The channel 320 may be formed by selecting an appropriate semiconductor according to a product design. For example, the channel 320 may be an oxide semiconductor, an organic semiconductor, amorphous silicon, poly-silicon, etc. For example, the oxide semiconductor may include zinc oxide (ZnO), InZnO(IZO), InGaZnO(IGZO), HfInZnO(HIZO), etc. in which zinc oxide (ZnO) is doped with indium (In), gallium (Ga), hafnium (Hf), t(Sn), etc. In at least some embodiments, the channel 320 may be an active region of a semiconductor material included in the substrate 310.

The source 332 and the drain 334 may be electrically connected through the channel 320. The source 332 and the drain 334 may include a conductive material, for example, a metal, a metal alloy, a conductive metal oxide, and/or a conductive metal nitride. The source 332 and the drain 334 may be formed in a monolayer structure or a multilayer structure. In at least some embodiments, the source 332 and the drain 334 may also be referred to as a source electrode and a drain electrode, respectively.

The gate 340 may include a conductive material, and may include metal, metal alloy, conductive metal oxide, and/or conductive metal nitride. In addition, the gate 340 may include a semiconductor material doped with impurities.

The gate insulating layer 350 is formed between the gate 340 and the channel 320. The gate insulating layer 350 may include the boron nitride film 11 according to at least one embodiment. Additionally, in at least some embodiments, spacers (not illustrated) between the gate 340 and the source 332 and/or the drain 334 include the boron nitride film 11 according to at least one embodiment.

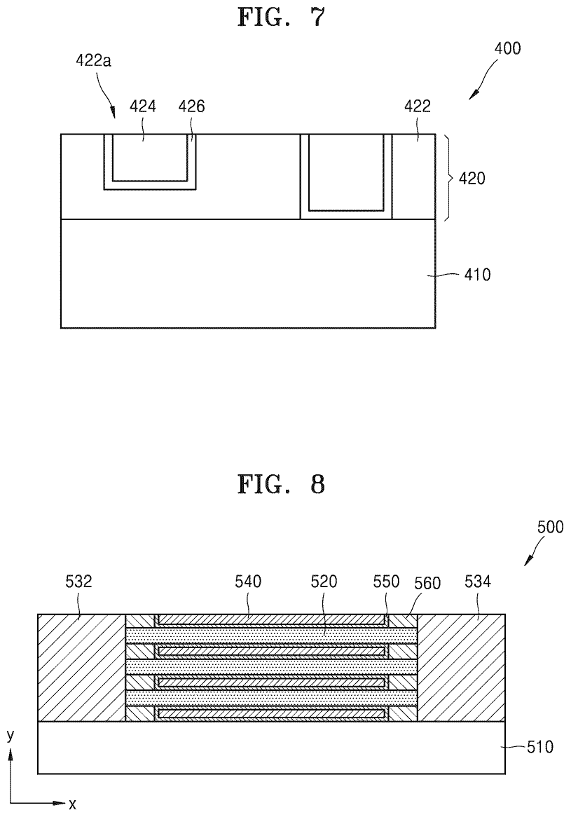

FIG. 7 is a diagram illustrating a semiconductor device 400 including a wiring structure 420.

Referring to FIG. 7, the semiconductor device 400 includes a substrate 410 and the wiring structure 420 provided on the substrate 410. Here, the wiring structure 420 may include a dielectric layer 422, a conductive wiring 424, and a diffusion barrier layer 426.

The substrate 410 may be a semiconductor substrate. For example, the substrate 410 may include a group IV semiconductor material, a group III/V semiconductor compound, or a group II/VI semiconductor compound. As a specific example, the substrate 410 may include Si, Ge, SiC, SiGe, SiGeC, Ge Alloy, GaAs, InAs, InP, etc. However, this is merely an example, and various other semiconductor materials may be used as the substrate 410.

The dielectric layer 422 is formed on the substrate 410. The dielectric layer 422 may have a single layer structure or a multilayer structure in which different materials are stacked. The dielectric layer 422 may include a dielectric material used in a general semiconductor manufacturing process. For example, the dielectric layer 422 may include silicon oxide, nitride, silicon nitride, silicate, etc. The dielectric layer 422 may include the boron nitride film 11 according to at least one embodiment. When the dielectric layer 422 includes the boron nitride film 11, because the dielectric layer 422 also performs a function of the diffusion barrier layer 426, which will be described below, the diffusion barrier layer 426 does not need to be provided separately.

The conductive wiring 424 may include metal or metal alloy with excellent electrical conductivity. For example, the conductive wiring 424 may include Cu, Ru, Al, Co, W, Mo, Ti, Ta, Ni, Pt, Cr, Rh, Ir, or alloys thereof. However, the disclosure is not limited thereto, and various other metals may be used as the conductive wiring 424.

The diffusion barrier layer 426 may be provided between the dielectric layer 422 and the conductive wiring 424 to cover the conductive wiring 424. An upper surface of the conductive wiring 424 may be exposed by the diffusion barrier layer 426. The diffusion barrier layer 426 may serve to prevent diffusion of materials forming the conductive wiring 424. Meanwhile, the diffusion barrier layer 426 may additionally serve as an adhesive layer between the dielectric layer 422 and the conductive wiring 424. The diffusion barrier layer 426 may include the boron nitride film 11 according to at least one embodiment.

Because the boron nitride film 11 grows at a low temperature, the boron nitride film 11 may be grown directly on some components of an electronic device. In addition, because a surface roughness of the boron nitride film 11 is low, other components of the electronic device may be directly stacked on the grown boron nitride film 11.

Meanwhile, as semiconductor devices are integrated, parasitic capacitance occurs between conductive material layers. The parasitic capacitance has the problem of delaying signal transmission of semiconductor devices. The boron nitride film 11 according to at least one embodiment has a low dielectric constant, and is used as an interlayer insulating film between conductive material layers, and thus, the parasitic capacitance may be reduced. In addition, the boron nitride film 11 may be processed at a low temperature, and may be formed directly on a material layer of the electronic device without damaging other materials in the electronic device.

FIG. 8 is a diagram illustrating a field effect transistor 500 including the boron nitride film 11 according to at least one embodiment. The field effect transistor 500 disclosed in FIG. 8 includes a plurality of channels 520 disposed on a substrate 510, a source 532 and a drain 534 in contact with the channels 520, and a plurality of gates 540 spaced apart from the plurality of channels 520.

The substrate 510 may be an insulating substrate and/or a semiconductor substrate with an insulating layer formed on its surface. The semiconductor substrate may include, for example, Si, Ge, SiGe, etc. The substrate 510 may be, for example, a silicon substrate with silicon oxide formed on its surface, but is not limited thereto.

On the substrate 510, the source 532 and the drain 534 may be spaced apart from each other in a first direction (X direction), and the plurality of channels 520 may be spaced apart in a second direction (Y direction) between the source 532 and the drain 534.

The plurality of gates 540 may be respectively spaced apart from the channels 520, and gate insulating layers 550 may be disposed between the gates 540 and the channels 520. For example, the gate insulating layers 550 may be provided to surround at least a part of the gates 540. For example, the gates 540 and the channels 520 may be alternately disposed in the second direction (Y direction), and the gate insulating layers 550 may surround the gates 540. The gate insulating layers 550 may insulate between the channels 520 and the gates 540 and may suppress leakage current.

A contact between each of the channels 520 and the source 532 and drain 534 may be in the form of an edge contact. For example, both ends of each of the channels 520 may contact the source 532 and the drain 534.

Meanwhile, each of the gates 540 may be spaced apart from the source 532 and the drain 534, and spacers 560 may be further disposed between the gate 540 and the source 532 and between the gate 540 and the drain 534. Because the source 532, the gates 540, and drain 534 are disposed in the first direction (X direction), parasitic capacitance may occur between the source 532 and the gate 540 and between the gate 540 and the drain 534. To reduce the parasitic capacitance, the spacer 560 may include the boron nitride film 11 according to at least one embodiment. In addition, the a-BN and the nc-BN according to at least one embodiment do not have porosity but have mechanical strength, and thus, the channel 520 disposed on an upper layer of the spacer 560 may be supported.

The field effect transistor 500 according to at least one embodiment may be in the shape of a multi-bridge in which the plurality of channels 520 each have both ends in contact with the source 532 and the drain 534 and spaced apart and stacked in a direction away from the substrate 510. A channel in the shape of the multi-bridge may reduce a short channel effect and reduce an area occupied by source/drain, and thus, the field effect transistor 500 may have a high integration. In addition, the field effect transistor 500 may maintain uniform source/drain junction capacitance regardless of a location of the channel, and thus, the field effect transistor 500 may be applied as a high-speed and high-reliability device.

The gate insulating layer 550 may include a high-k dielectric material. The high-k dielectric material may have a dielectric constant greater than that of SiO₂. The gate insulating layer 550 may include, for example, aluminum oxide, hafnium oxide, zirconium hafnium oxide, or lanthanum oxide. However, the disclosure is not limited thereto.

In at least some embodiments, the gate insulating layer 550 may include a ferroelectric material. When the gate insulating layer 550 includes a ferroelectric material, the field effect transistor 500 may be applied as, for example, a logic device or a memory device. When the gate insulating layer 550 includes a ferroelectric material, subthreshold swing (SS) may be lowered due to the negative capacitance effect, thereby reducing the size of the field effect transistor 500 and improving performance thereof.

The ferroelectric material may have a spontaneous electric dipole due to non-centrosymmetric charge distribution in a unit cell of a crystallized material structure, that is, spontaneous polarization. Therefore, the ferroelectric material may have remnant polarization due to dipoles even in the absence of an external electric field. In addition, directions of polarization may be switched in a domain unit by an external electric field. The ferroelectric material may include, for example, at least one oxide selected from Hf, Si, Al, Zr, Y, La, Gd, and/or Sr with a ferroelectric phase, but this is an example. In addition, if necessary, the ferroelectric material may further include a dopant.

The gate insulating layer 550 may have a multilayer structure including a high-k material and a ferroelectric material. The gate insulating layer 550 includes a charge trapping layer such as silicon nitride, and thus, the field effect transistor 500 may operate as a memory transistor having memory characteristics.

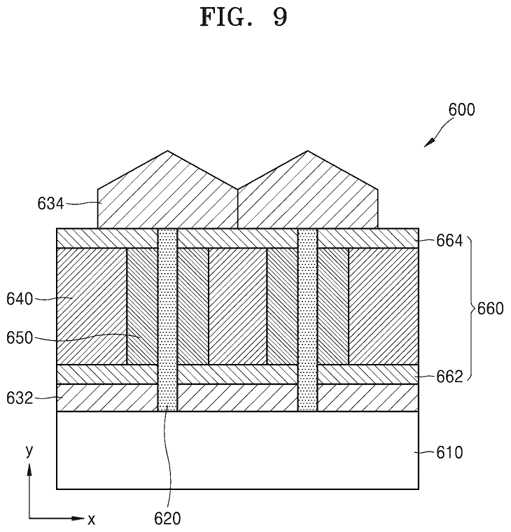

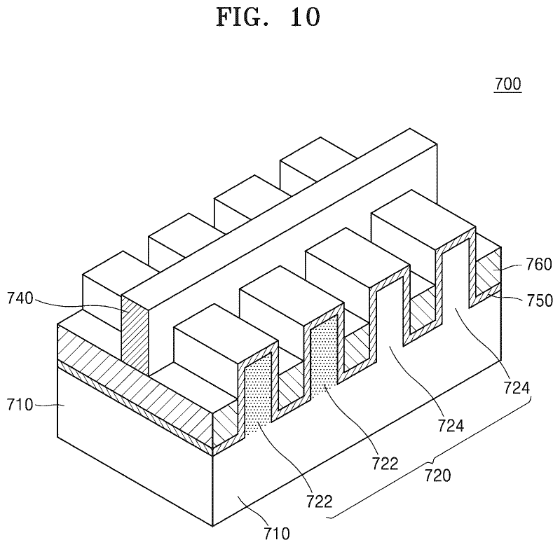

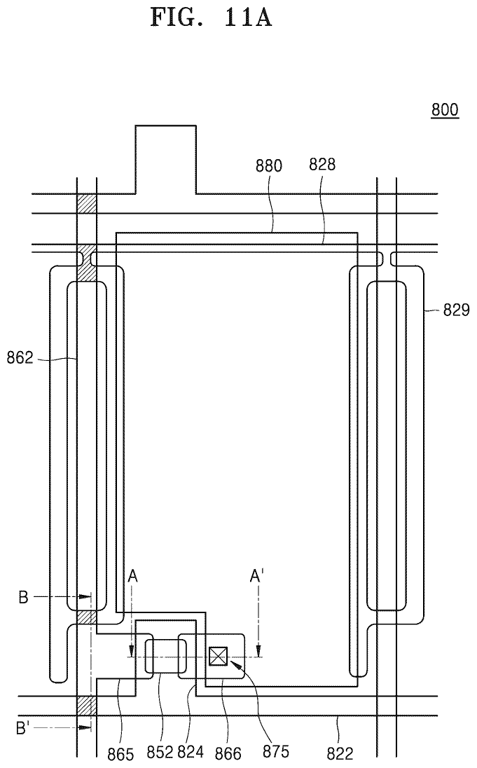

FIG. 9 is a diagram illustrating a vertical field effect transistor 600 including the boron nitride film 11 according to at least one embodiment. The field effect transistor 600 may be referred to as the vertical field effect transistor because current flows in a vertical direction through channels 620 extending from a substrate 610 in the vertical direction. The field effect transistor 600 may include the substrate 610, the channels 620, a source 632, a drain 634, gates 640, gate insulating layers 650, and a spacer 660. The spacer 660 may include a first spacer 662 (e.g., a lower spacer 662) and a second spacer 664 (e.g., an upper spacer 664).

The substrate 610 may include, for example, one or more semiconductor materials, such as Si, Ge, SiGe, GaP, GaAs, SiC, SiGeC, and/or InP. In some embodiments, the substrate 610 may be a bulk silicon substrate or an SOI substrate.

The channels 620 may be spaced apart from each other in a first direction (e.g., X-axis direction). The first direction may be parallel to an upper surface of the substrate 610. Each of the channels 620 may protrude from the upper surface of the substrate 610 in a second direction (e.g., Y-axis direction). The second direction may be perpendicular to the upper surface of the substrate 610. Forming the channel 620 may include forming a mask layer (not shown) on the substrate 610 and etching the substrate 610 by using the mask layer as an etch mask.

The source 632 may be disposed on the substrate 610. The source 632 may be in contact with a part of each of the channels 620 while surrounding the channels 620. The source 632 may be formed by performing an epitaxial growth process by using the substrate 610 as a seed layer, and impurities may be added during the epitaxial growth process. However, the disclosure is not limited thereto. The source 632 may be formed by injecting impurities into the substrate 610. In addition, the source 632 is disposed in contact with side surfaces of each of the channels 620, but the source 632 is not limited thereto and may be disposed in contact with a lower surface of each of the channels 620.

The first spacer 662 may be disposed on the source 632, and the gates 640 and the gate insulating layers 650 may be disposed on the first spacer 662. The first spacer 662 may be provided to surround a part of the side surfaces of each of the channels 620, and the gates 640 may be disposed on the first spacer 662 and spaced apart from the channels 620. The gate insulating layers 650 may be disposed on the first spacer 662 and between the gates 640 and the channels 620. The gate insulating layer s650 and the gates 640 may also extend on the first spacer 662 in the vertical direction.

The second spacer 664 may be disposed on the gates 640 and the gate insulating layers 650, and provided to surround a part of the side surfaces of each of the channels 620.

Also, the drain 634 may be provided on the channels 620. The drain 634 may be formed by the epitaxial growth process using the channels 620 as the seed layer. The drain 634 may be disposed to cover at least a part of the second spacer 664.

The first spacer 662 and the second spacer 664 each may include the boron nitride film 11 according to at least one embodiment. The first spacer 662 and the second spacer 664 each may further include a material with a low dielectric constant, in addition to the boron nitride film 11 according to at least one embodiment.

In addition, because the boron nitride film 11 according to at least one embodiment has a high thermal conductivity, heat may be easily dissipated through the first spacer 662 and the second spacer 664.

In addition, the first spacer 662 may be formed after forming the source 632, and the second spacer 664 may be formed after forming the gate 640 and the gate insulating layer 650. The first spacer 662 and the second spacer 664 may be formed by forming an amorphous boron nitride film or a nanocrystal boron nitride film at a low temperature, and thus, the source 632 and the gates 640 may not be damaged.

FIG. 9 shows that the source 632 is formed below the channels 620 and the drain 634 is formed on the channels 620, but the disclosure is not limited thereto. The drain 634 may be formed below the channels 620 and the source 632 may be formed on the channels 620.

FIG. 10 is a diagram illustrating a fin type transistor 700 including the boron nitride film 11 according to at least one embodiment. The fin type transistor 700 is a stereoscopic transistor having a fin structure protruding from a substrate 710. The fin type transistor 700 may use protruding fin structures 722 and 724 as channels 720, and thus, a sufficient channel length may be secured. Accordingly, a short channel effect may be prevented or minimized, and problems of generation and area of leakage current may be improved.

The fin type transistor 700 may include the substrate 710, active fins 722, dummy fins 724, a gate 740, a gate insulating layer 750, and spacers 760. Although not shown in FIG. 10, both ends of the active pin 722 are electrically connected to a source and a drain, respectively.

The substrate 710 may be a semiconductor substrate, and may include one of, for example, silicon, an SOI, silicon-on-sapphire, germanium, silicon-germanium, and gallium-arsenide.

The active fins 722 and the dummy fins 724 may be connected to the substrate 710. In at least one embodiment, the active fins 722 may be active regions in which parts vertically protruding from the substrate 710 are doped with n+ or p+, and the dummy fins 724 may be non-doped regions in which parts vertically protruding from the substrate 710 are not doped. In another embodiment, both the active fins 722 and the dummy fins 724 may be active regions doped with n+ or p+.

Each of the active fins 722 may have a width and a height, and the width and height of each of the active fins 722 may determine a width and a height of each of the channels 720. The width and the height of each of the channels 720 may be increased by the number of the active fins 722.

The gate insulating layer 750 may be disposed on the active fin 722 and the dummy fin 724. The gate insulating layer 750 may include any one of an oxide film, a nitride film, and an oxynitride film. Alternatively, the gate insulating layer 750 may include the boron nitride film 11 according to at least one embodiment.

The spacers 760 each may be disposed to have a certain height in the space between the active fins 722 and the dummy fins 724. The spacers 760 each may include the boron nitride film 11 according to at least one embodiment and thus, include a material having a low dielectric constant and a high thermal conductivity. The spacers 760 are disposed between the active fins 722 and the dummy fins 724, and thus, the spacers 760 may not only be used as device isolation layers but also reduce parasitic capacitance.

The gate 740 may be disposed on the gate insulating layer 750 and the spacers 760. Accordingly, the gate 740 may have a structure surrounding the active fins 722, the dummy fins 724, and the spacers 760. In other words, the active fins 722 and the dummy fins 724 may have a structure disposed inside the gate 740. The gate 740 may include a metal material such as W and Ta, nitrides thereof, silicides thereof, doped polysilicon, etc., and may be formed by using a deposition process.

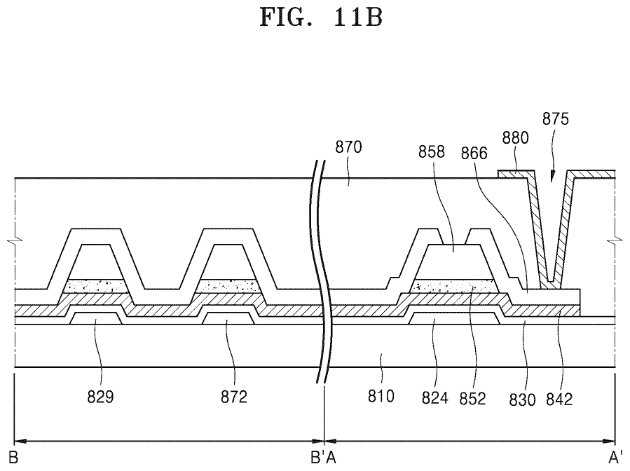

FIGS. 11A and 11B are diagrams illustrating a part of a display apparatus 800 including the boron nitride film 11 according to at least one embodiment. FIG. 11A is a diagram illustrating a part of the display apparatus 800 including the boron nitride film 11 according to at least one embodiment, and FIG. 11B is a cross-sectional view taken along lines A-A′ and B-B′ of FIG. 11A.

Referring to FIGS. 11A and 11B, gate wirings 822 and 824 that transmit gate signals are formed on an insulating substrate 810. The gate wirings 822 and 824 include the gate wiring 822 that extends in one direction, for example, a horizontal direction, and the gate wiring 824 of a thin film transistor that protrudes from the gate wiring 822 in the form of a protrusion.

In addition, storage wirings 828 and 829 that transmit storage voltages are formed on the insulating substrate 810. The storage wirings 828 and 829 include the storage wiring 828 formed substantially parallel to the gate wiring 822 across a pixel region, and the storage wiring 829 branched from the storage wiring 828 and extending parallel to a data wiring 862.

The storage wiring 829 may be formed in the shape of a square ring formed along the data wiring 862. That is, an opening region is formed in the center of the storage wiring 829 so that the data wiring 862 is located, and at least a part of a ring portion of the storage wiring 829 overlaps a pixel electrode 880.

The shape and arrangement of the storage wiring 829 and the storage wiring 828 may be modified into various forms, and, when storage capacitance generated by the overlap of the pixel electrode 880 and the gate wiring 822 is sufficient, the storage wiring 829 and the storage wiring 828 may not be formed.

The gate wirings 822 and 824 and the storage wirings 828 and 829 may include aluminum-based metal such as aluminum (Al) and aluminum alloy, silver-based metal such as silver (Ag) and silver alloy, copper-based metal such as copper (Cu) and copper alloy, molybdenum-based metal such as molybdenum (Mo) and molybdenum alloy, chromium (Cr), titanium (Ti), tantalum (Ta), etc. In addition, the gate wirings 822 and 824 and the storage wirings 828 and 829 each may have a multilayer structure including two conductive layers (not shown) having different physical properties. One of the two conductive layers includes a metal having a low resistivity, such as aluminum-based metal, silver-based metal, or copper-based metal, to reduce a signal delay or a voltage drop of the gate wirings 822 and 824 and the storage wirings 828 and 829. In contrast, the other conductive layer includes a material having excellent contact characteristics, such as molybdenum-based metals, chromium, titanium, or tantalum, with other materials, especially zinc oxide (ZnO), indium tin oxide (ITO), and indium zinc oxide (IZO). Good examples of such combinations may include a chromium lower layer and an aluminum upper layer, an aluminum lower layer and a molybdenum upper layer, and a titanium lower layer and a copper upper layer. However, the disclosure is not limited thereto, and the gate wirings 822 and 824 and the storage wirings 828 and 829 may include various metals and conductors.

A gate insulating layer 830 is formed on the insulating substrate 810, the gate wirings 822 and 824, and the storage wirings 828 and 829. The gate insulating layer 830 may include silicon oxide (SiOx), silicon nitride (SiNx), or silicon oxynitride (SiON). Specifically, the gate insulating layer 830 may be formed as a single layer or a multilayer, and when formed as the multilayer, the gate insulating layer 830 may have a structure in which silicon nitride and silicon oxide are stacked. At this time, the gate insulating layer 830 may be formed as a silicon oxide layer in a region in contact with an oxide semiconductor layer pattern 842, and a nitrogen oxide layer may be disposed below the silicon oxide layer. When the silicon oxide layer contacts the oxide semiconductor layer pattern 842, deterioration of the oxide semiconductor layer pattern 842 may be prevented. When the gate insulating layer 830 is formed as a silicon oxynitride layer, the silicon oxynitride layer may have an oxygen concentration distribution. Even in this case, deterioration of the oxide semiconductor layer pattern 842 may be prevented by increasing the oxygen concentration as the silicon oxynitride layer is close to the oxide semiconductor layer pattern 842.

The oxide semiconductor layer pattern 842 for forming a channel of the thin film transistor is formed on the gate insulating layer 830. A channel region may be formed by the oxide semiconductor layer pattern 842 that overlaps the gate wiring 824. In the embodiment, the oxide semiconductor layer pattern 842 may be formed to have substantially the same shape as the data wirings 862, 865, and 866, which will be described below, except for the channel region. This is because, in a process of manufacturing a substrate of the thin film transistor, the oxide semiconductor layer pattern 842 and the data wirings 862, 865, and 866 are patterned by using one etch mask. In other words, the oxide semiconductor layer pattern 842 may have the same shape as the data wirings 862, 865, and 866, except that the oxide semiconductor layer pattern 842 is formed in the channel region.

The oxide semiconductor layer pattern 842 includes a compound having a chemical formula expressed as, for example, A_{X}B_{X}O_{X} and/or A_{X}B_{X}C_{X}O_{X}. A includes Zn or Cd, B includes Ga, Sn or In, and C includes Zn, Cd, Ga, In, or Hf. X is an integer greater than 0, and A, B and C are different from each other. According to another embodiment, the oxide semiconductor layer pattern 842 may include any one material selected from the group consisting of InZnO, InGaO, InSnO, ZnSnO, GaSnO, GaZnO, GaZnSnO, GaInZnO, HfInZnO, and ZnO. Such an oxide semiconductor has a semiconductor characteristic with an effective mobility of charges that is about 2 to about 100 times better than that of hydrogenated amorphous silicon.

Etch prevention patterns 852 are formed on the oxide semiconductor layer pattern 842. Here, the etch prevention patterns 852 are respectively formed on a thin film transistor region where the gate wiring 824 and the data wirings 865 and 866 overlap, a region where the gate wiring 822 and the data wiring 862 overlap (hereinafter referred to as a first overlap region), and a region where the storage wirings 828 and 829 and the data wiring 862 overlap (hereinafter referred to as a second overlap region).

The etch prevention pattern 852 formed on the thin film transistor region is configured to prevent (and/or reduce the harm to) the oxide semiconductor layer pattern 842 from being damaged by plasma, etchant, or etching gas during a subsequent etching or deposition process. This is because when the oxide semiconductor layer pattern 842 is damaged by plasma, etchant, or etching gas, the performance of the thin film transistor may be greatly reduced. Accordingly, the etch prevention pattern 852 formed on the thin film transistor region is formed to cover the oxide semiconductor layer pattern 842, especially to cover the channel region. That is, in order to prevent (and/or reduce) the oxide semiconductor layer pattern 842 from being exposed in the channel region, the etch prevention pattern 852 may be formed wider in a longitudinal direction of the channel than the channel region on a region overlapping with the channel region.

On the other hand, the etch prevention pattern 852 formed on the first overlap region is further provided to reduce the capacitance occurring between the gate wiring 822 and the data wiring 862 in the first overlap region, and the etch prevention pattern 852 formed on the second overlap region is provided to reduce the capacitance occurring between the storage wirings 828 and 829 and the data wiring 862 in the second overlap region. This is because the capacitance occurring between the gate wiring 822 and the data wiring 862 or the capacitance occurring between the storage wirings 828 and 829 and the data wiring 862 causes a resistive-capacitive (RC) delay. Accordingly, the etch prevention patterns 852 are formed on the oxide semiconductor layer pattern 842 on the first overlap region and the second overlap region.

The etch prevention pattern 852 may include an insulating material, for example, any material selected from the group consisting of SiOx and SiNx.

The data wiring 862 is formed on the gate insulating layer 830, the oxide semiconductor layer pattern 842, and the etch prevention pattern 852. The data wiring 862 may be formed in a direction different from the gate wiring 822, for example, in a vertical direction, crossing the gate wiring 822, and define a pixel. The source wiring 865 may branch from the data wiring 862 into the shape of a branch and extend to upper portions of the oxide semiconductor layer pattern 842 and the etch prevention pattern 852 on the thin film transistor region. The drain wiring 866 may be formed on the upper portions of the oxide semiconductor layer pattern 842 and the etch prevention pattern 852 on the thin film transistor region so as to be spaced apart from the source wiring 865 and face the source wiring 865 with respect to the gate wiring 824.

At least a part of the etch prevention pattern 852 is exposed between the source wiring 865 and the drain wiring 866. The oxide semiconductor layer pattern 842 is disposed below the etch prevention pattern 852, the source wiring 865, and the drain wiring 866. That is, the oxide semiconductor layer pattern 842 completely overlaps the etch prevention pattern 852 and the source wiring 865 and the drain wiring 866. As described above, the source wiring 865 and the drain wiring 866 have substantially the same shape as the oxide semiconductor layer pattern 842 except for an isolation region overlapping the channel region.

The data wiring 862, the source wiring 865, and the drain wiring 866 may be formed in a single layer structure or a multilayer structure including Ni, Co, Ti, Ag, Cu, Mo, Al, Be, Nb, Au, Fe, Se, W, Ru, or Ta. In addition, alloys including one or more elements selected from Ti, Zr, W, Ta, Nb, Pt, Hf, O, C, and N in metal are also applicable. Examples of the multilayer structure may include a double layer such as Ti/Cu, Ta/Al, Ta/Al, Ni/Al, Co/Al, Mo(Mo alloy)/Cu, etc., or a triple layer such as Mo/Al/Mo, Ti/Al/Ti, Ta/Al/Ta, Ti/Al/TiN, Ta/Al/TaN, Ni/Al/Ni, Co/Al/Co, etc. However, the data wiring 862, the source wiring 865, and the drain wiring 866 are not limited to the materials described above.

A low dielectric material pattern 858 may be further formed on the upper portion of the etch prevention pattern 852. The low dielectric material pattern 858 may be formed to have a substantially similar shape as the etch prevention pattern 852. The low dielectric material pattern 858 may include the boron nitride film 11 according to at least one embodiment.

Further forming the low dielectric material pattern 858 on the upper portion of the etch prevention pattern 852 is to further reduce the capacitance occurring between the gate wiring 822 and the data wiring 862 in the first overlap region and the capacitance occurring between the storage wirings 828 and 829 and the data wiring 862 in the second overlap region and shorten the process time.

That is, the larger the sum of the thickness of the etch prevention pattern 852 and the thickness of the low dielectric material pattern 858, the greater the capacitance occurring between the gate wiring 822 and the data wiring 862 in the first overlap region and the capacitance occurring between the storage wirings 828 and 829 and the data wiring 862 in the second overlap region may be further reduced.

In addition, the thickness of the low dielectric material pattern 858 may be greater than the thickness of the etch prevention pattern 852, and accordingly, the process time may be shortened.

In the present embodiments, a structure in which the low dielectric material pattern 858 is stacked on the upper portion of the etch prevention pattern 852 has been described, but the disclosure is not limited thereto, and the stacking order may be switched. That is, the etch prevention patterns 852 may be stacked on an upper portion of the low dielectric material pattern 858.

A protective layer 870 is formed on the data wirings 862, 865, and 866 and the upper portion of the etch prevention pattern 852 exposed by the data wirings 862, 865, and 866. Like the gate insulating layer 830, the protective layer 870 may include silicon oxide (SiOx), silicon nitride (SiNx), or silicon oxynitride (SiON). According to at least one embodiment, the protective layer 870 may include a double layer including silicon nitride (SiNx) and silicon oxide (SiOx). A contact hole 875 is formed in the protective layer 870 to expose a part of the data wiring 866.

A pixel electrode 880 is formed on the protective layer 870 and is electrically connected to the data wiring 866 through a contact hole 875. The pixel electrode 880 may include a transparent conductor such as ITO or IZO, or a reflective conductor such as aluminum.

The pixel electrode 880 to which a data voltage is applied may control light emission in a pixel region (not shown) together with a common electrode of an upper substrate facing the substrate of the thin film transistor.

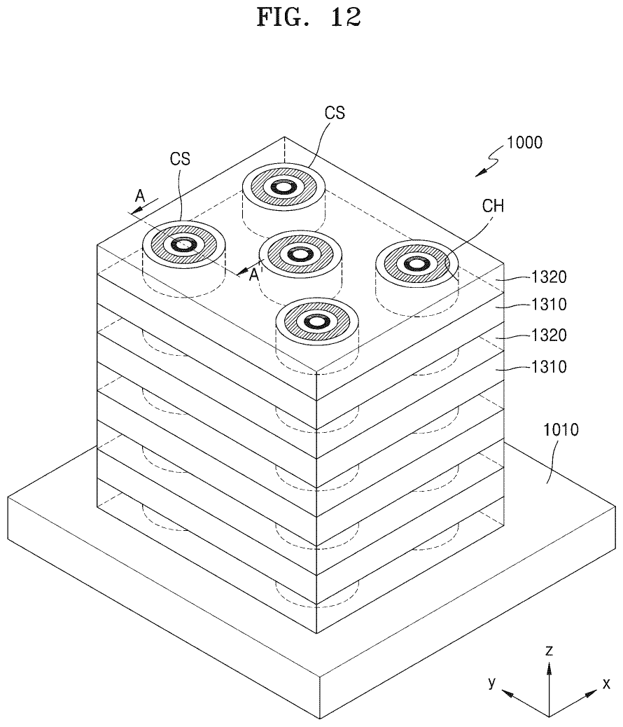

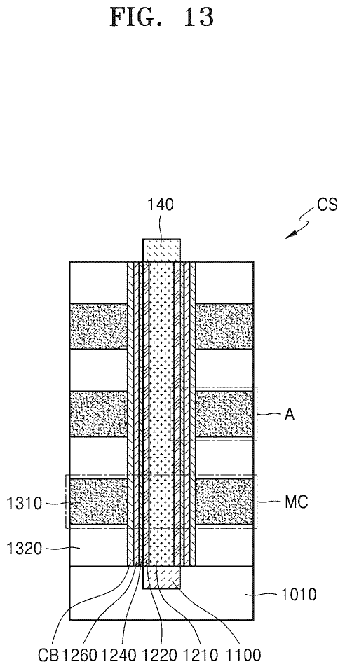

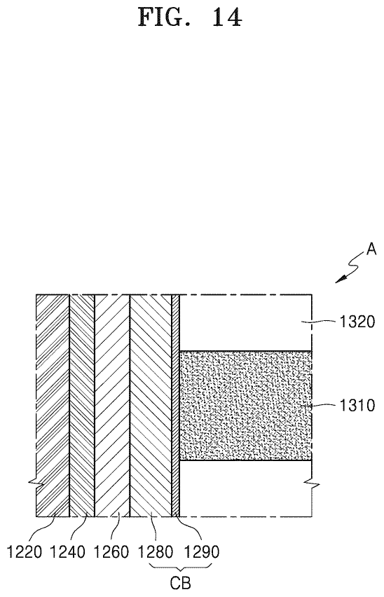

FIG. 12 is a perspective view schematically illustrating a nonvolatile memory device 1000 according to at least one embodiment, FIG. 13 is a cross-sectional view taken along line A-A′ of FIG. 12, and FIG. 14 is an enlarged view of part A of FIG. 13.

Referring to FIG. 12, the nonvolatile memory device 1000 includes a plurality of cell strings CS disposed on a substrate 1010. Here, each of the cell strings CS may be provided to extend in a direction (Z-axis direction in FIG. 12) perpendicular to the substrate 1010. The plurality of cell strings CS may be arranged on the substrate 1010 in various shapes. Gate electrodes 1310 and boron nitride films 1320 may be alternately stacked on the substrate 1010. The boron nitride film 1320 is substantially the same as that described with reference to FIG. 1, and thus, a detailed description thereof is omitted here. A channel hole CH may be provided to penetrate a stack structure of the gate electrode 1310 and the boron nitride film 1320 in the direction (Z-axis direction) perpendicular to the substrate 1010. The channel hole CH may be formed to have, for example, a circular cross-section. However, the cross-sectional shape of the channel hole CH is not limited thereto.

A region of the cell string CS excluding the gate electrode 1310 and the boron nitride film 1320 may have a stacked structure of a plurality of cylindrical shells in the channel hole CH. However, the structure of the cell string CS is not limited thereto and may have other forms and structures.

The substrate 1010 may include a single crystal silicon substrate, a compound semiconductor substrate, or an SOI substrate, but is not limited thereto. In addition, the substrate 1010 may further include, for example, an impurity region caused by doping, an electronic device such as a transistor, or a periphery circuit that selects and controls memory cells that store data.

Referring to FIG. 13, the cell string CS may include a plurality of memory cells MC stacked in the direction (Z-axis direction) perpendicular to the substrate 1010. The memory cell MC may be a basic unit cell that writes and erases data.

The cell string CS may include a pillar 1210 extending in a direction perpendicular to the substrate 1010, a channel layer 1220 provided in the pillar 1210, a charge tunneling layer 1240 provided in the channel layer 1220, a charge trap layer 1260 provided in the charge tunneling layer 1240, a charge blocking layer CB provided in the charge trap layer 1260, and a gate electrode 1310 provided in the charge blocking layer CB.

The pillar 1210 may include, for example, an insulator (e.g., silicon oxide) and/or air, but is not limited thereto. Each of the channel layer 1220, the charge tunneling layer 1240, and the charge trap layer 1260 may be provided to extend in perpendicular to the substrate 1010 and shared by the plurality of memory cells MC.

The channel layer 1220 may include a semiconductor material. The channel layer 1220 may include, for example, Si, Ge, SiGe, or a group III-V semiconductor. In addition, the channel layer 1220 may include, for example, an oxide semiconductor, a nitride semiconductor, a nitride semiconductor, a 2D semiconductor material, a quantum dot, or an organic semiconductor. Here, the oxide semiconductor may include, for example, InGaZnO, etc. The 2D semiconductor material may include, for example, transition metal dichalcogenide (TMD) and/or doped-graphene, and the quantum dot may include a colloidal quantum dot (QD), a nanocrystal structure, etc. The 2D semiconductor material refers to a semiconductor material with a 2D crystal structure and may have a monolayer structure or a multilayer structure. The 2D semiconductor material may have excellent electrical characteristics and be a material applicable to various devices because the 2D semiconductor material maintains high mobility even when the thickness is reduced to nanoscale without significant changes in the characteristics. Each of layers of the 2D semiconductor material may have a thickness of an atomic level. The channel layer 1220 may include 1 to 10 2D semiconductor material layers.

The 2D semiconductor material may include, for example, at least one of graphene, black phosphorous, or TMD. Graphene is a material that has a hexagonal honeycomb structure in which carbon atoms are 2D bonded. Compared to silicon (Si), graphene has a high electrical mobility, excellent thermal characteristics, a chemical stability, and a large surface area and can be doped to be semiconductive. Also, the black phosphorus is a material in which black phosphorous atoms are 2D bonded.

The TMD may be expressed, for example, as MX₂, where M denotes a transition metal, and X denotes a chalcogen element. For example, M may include Mo, W, Nb, V, Ta, Ti, Zr, Hf, Tc, or Re, and X may include S, Se, or Te. Thus, for example, the TMD may include MoS₂, MoSe₂, MoTe₂, WS₂, WSe₂, Wte₂, ZrS₂, ZrSe₂, HfS₂, HfSe₂, NbSe₂, or ReSe₂.

Alternatively, the 2D semiconductor material may include CuS, which is a compound of Cu (that is a transition metal) and S (that is a chalcogen element). Meanwhile, the 2D semiconductor material may be a chalcogenide material containing a non-transition metal. The non-transition metal may include, for example, Ga, In, Sn, Ge, Pb, etc. In this case, the 2D semiconductor material may include a compound of a non-transition metal such as Ga, In, Sn, Ge, and Pb and a chalcogen element such as S, Se, and Te. For example, the 2D semiconductor material may include SnSe₂, GaS, GaSe, GaTe, GeSe, In₂Se₃, InSnS₂, etc. However, the materials mentioned above are merely examples, and other materials may be used as the 2D semiconductor material.

The channel layer 1220 may further include a dopant. Here, the dopant may include a p-type dopant or an n-type dopant. The p-type dopant may include, for example, a Group III element such as B, Al, Ga, In, etc., and the n-type dopant may include a Group V element such as P, As, Sb, etc.

The charge tunneling layer 1240 is a layer in which charge tunneling occurs and may include, for example, silicon oxide or metal oxide, but is not limited thereto.

The gate electrodes 1310 are stacked spaced apart from each other in the direction perpendicular to the substrate 1010, and a boron nitride film 1320 may be provided between the gate electrodes 1310. The boron nitride film 1320 may electrically separate the gate electrodes 1310 such that the gate electrodes 1310 may be driven independently in the unit of the memory cell MC and include the boron nitride film 11 according to at least one embodiment. Although FIG. 12 does not illustrate a source electrode and a drain electrode, FIG. 13 illustrates a source electrode 1100 and a drain electrode 1400. The source electrode 1100 may be disposed under the channel layer 1220, and the drain electrode 1400 may be disposed on the channel layer 1220. The drain electrode 1400 may be connected to a bit line (not shown).

Although FIG. 13 illustrates that the source electrode 1100 is connected to each cell string CS, the source electrode 1100 may be commonly connected to the cell string CS. FIG. 13 illustrates that the charge blocking layer CB includes a single layer for convenience, but the disclosure is not limited thereto, and the charge blocking layer CB may include multiple layers.

The channel layer 1220 may be disposed to surround a lateral surface of the pillar 1210, the charge tunneling layer 1240 may be disposed to surround a lateral surface of the channel layer 1220, the charge trap layer 1260 may be disposed to surround a lateral surface of the charge tunneling layer 1240, and the charge blocking layer CB may be disposed to surround a lateral surface of the charge trap layer 1260.

In addition, the gate electrode 1310 and the boron nitride film 1320 may be alternately disposed along the lateral surface of the charge blocking layer CB. Each channel corresponding to the gate electrode 1310 may be formed in the channel layer 1220 between the source electrode 1100 and the drain electrode 1400. When a certain voltage is applied to the gate electrode 1310 from each of the memory cells MC, charges flowing between the source electrode 1100 and the drain electrode 1400 in the channel layer 1220 corresponding to the gate electrode 1310 may pass through the charge tunneling layer 1240 and may be trapped in the charge trap layer 1260 to store information.

The gate electrode 1310 may control the corresponding channel layer 1220, and a word line may be electrically connected to the gate electrode 1310. The gate electrode 1310 may include a metal material having excellent electrical conductivity, a conductive oxide, a metal nitride, silicon doped with impurities, a 2D conductive material, etc. The metal material may include, for example, Au, Ti, TiN, TaN, W, Mo, WN, Pt, Nb, NbN, Ni, and/or a combination thereof. The conductive oxide may include, for example, ITO, IZO, etc. However, this is merely an example, the gate electrode 1310 may include various other materials. The boron nitride film 1320 may serve as a spacer layer for insulation between the gate electrodes 1310.

The boron nitride film 1320 may have a thickness in a range of about 1 nanometer (nm) to about 1 micrometer (μm). Alternatively, the boron nitride film 1320 may have a thickness in a range of about 5 nm to about 100 nm. For example, the boron nitride film 1320 may have a thickness in a range of about 5 nm to about 16 nm. Here, the thickness indicates a stacking direction of the gate electrode 1310 and the boron nitride film 1320, that is, a thickness in the Z-axis direction in FIG. 12. The boron nitride film 1320 may have a thickness less than or equal to the thickness of the gate electrode 1310. A ratio (d2/d1) of a thickness d2 of the boron nitride film 1320 to a thickness d1 of the gate electrode 1310 may be about 0.5 to about 1. Alternatively, the ratio (d2/d1) of the thickness d2 of the boron nitride film 1320 to the thickness d1 of the gate electrode 1310 may be about 0.7 to about 1. Alternatively, the ratio (d2/d1) of the thickness d2 of the boron nitride film 1320 to the thickness d1 of the gate electrode 1310 may be about 0.8 to about 1.

The charge blocking layer CB may serve as a barrier blocking a charge migration between the charge trap layer 1260 and the gate electrode 1310. One surface of the charge blocking layer CB may be in contact with the charge trap layer 1260, and another surface of the charge blocking layer CB may be in contact with the gate electrode 1310.

The charge trap layer 1260 may store introduced charges. Charges (e.g., electrons) present in the channel layer 1220 may be introduced into the charge trap layer 1260 by the tunneling effect, etc. Charges introduced into the charge trap layer 1260 may be trapped in the charge trap layer 1260.

The reliability element, which is a key requirement in the nonvolatile memory device 1000, relates to retention of data, e.g., characteristics of storing charges in the charge trap layer 1260 for a long time. When a distance between the memory cells MC is reduced to increase the density of memory in the nonvolatile memory device 1000, migration of charges trapped between the memory cells MC may occur, which may lead to degradation of charge retention characteristics.

In a direction perpendicular to the charge trap layer 1260, charges may migrate from the charge trap layer 1260 to the charge tunneling layer 1240 by trap-assisted tunneling or thermal emission. A degree of such migration of charges may be determined by a conduction band offset (CBO) at an interface of the charge trap layer 1260 and the charge tunneling layer 1240.

In a direction parallel with the charge trap layer 1260, charge migration may occur by lateral migration due to a gradient of the charge concentration. The charge migration in the direction parallel with the charge trap layer 1260 may be governed by Poole-Frenkel tunneling. The current density by Poole-Frenkel tunneling may be expressed by Poole-Frenkel conduction equation (Equation 1):

$$J = q μ {N}_{c} E exp ( \frac{- q ( {E}_{T} - \sqrt{qE / πε}}{kT} ) \qquad ( equation 1 )$$

(J: current density, q: electronic charge, μ: carrier mobility, N_{c}: density of states in conduction band, E: electric field, E_{T}: trap energy, ε: permittivity, k: Boltzmann constant, T temperature).

The charge migration in the direction parallel with the charge trap layer 1260 due to Poole-Frenkel tunneling may be determined by the trap energy E_{T} and the trap density N_{T} in the charge trap layer 1260. The trap energy E_{T} is a voltage barrier which electrons may cross to move from one atom to another atom in a material. That is, the trap energy E_{T} may refer to a depth of a trap state with respect to a conduction band minimum (CBM) of a material. The trap density N_{T} may refer to the number of charges trapped per unit volume. The trap density N_{T} may be calculated by using a charge pumping method. The charge retention characteristics in the direction parallel with the charge trap layer 1260 may be improved by high trap energy E_{T} and high trap density N_{T}.

The charge trap layer 1260 may include, for example, at least one of silicon nitride (SiN), gallium nitride (GaN), gallium oxide (GaO), hafnium oxide (HfO), scandium oxide (ScO), strontium oxide (SrO), zirconium oxide (ZrO), yttrium oxide (YO), tantalum oxide (TaO), barium oxide (BaO), or zinc sulfide (ZnS), and/or the like.

Alternatively, the charge trap layer 1260 may include a matrix and nano crystals in the matrix. The matrix may include an amorphous metal oxynitride. The matrix may include a metal oxynitride having a greater permittivity than a silicon nitride. For example, the matrix may include at least one of AlON, ZrON, LaON, AlSiON, HfAlON, LaSiON, AlZrON, LaAlON, HfAlON, ZrSiON, etc. However, the disclosure is not limited thereto. For example, the nano crystals may include at least one of AlN, GaN, GeN, SiN, CN, InN, YN, ScN, ZrN, etc. However, the disclosure is not limited thereto.

As the charge trap layer 1260 includes an amorphous metal oxynitride in which nano crystals having semiconductor characteristics are dispersed, the trap energy E_{T} and the trap density N_{T} may increase, and the charge retention characteristics may be improved by suppressing the migration of charges trapped between the memory cells MC. Accordingly, a threshold voltage may decrease, and thus, memory operation characteristics may be improved.

The charge blocking layer CB may prevent leakage of charges over the charge trap layer 1260 to the boron nitride film 1320 and the gate electrode 1310. The charge blocking layer CB may include, for example, a first charge blocking layer 1280 disposed on the charge trap layer 1260 and a second charge blocking layer 1290 disposed on the first charge blocking layer 1280. The first charge blocking layer 1280 may be in direct contact with the charge trap layer 1260. However, the disclosure is not limited thereto, and another layer may be disposed between the charge trap layer 1260 and the first charge blocking layer 1280. The first charge blocking layer 1280 may include, for example, a silicon oxide, a metal oxide, or a metal nitride, but the disclosure is not limited thereto. The first charge blocking layer 1280 may include at least one of aluminum oxide (AlO), magnesium oxide (MgO), aluminum nitride (AlN), or gallium nitride (GaN). The first charge blocking layer 1280 may include, for example, SiO₂ or Al₂O₃.

The second charge blocking layer 1290 may include a ferroelectric material and/or an anti-ferroelectric material. The ferroelectric material is a material having ferroelectricity in which electric dipole moments are aligned and spontaneous polarization is maintained even when no external electric field is applied thereto. The ferroelectric material may show spontaneous polarization by permanent dipole moments aligned in the same direction. The ferroelectric material may have remnant polarization by dipole even when there is no external electric field. Moreover, polarization directions may switch in a domain unit by an external electric field. The threshold voltage of the nonvolatile memory device 1000 may change according to the switching of the polarization direction of the ferroelectric material, for example, from the gate electrode 1131 toward the channel layer 1122 or from the channel layer 1122 toward the gate electrode 1131.

The anti-ferroelectric material may include an array of electric dipoles, but the remnant polarization may be 0 or close to 0. When there is no electric field, because directions of adjacent dipoles are opposite to each other and then offset, the overall spontaneous polarization and remnant polarization may be 0 or close to 0. However, when an external electric field is applied, the anti-ferroelectric material may show the polarization characteristics and switching characteristics.

The ferroelectric material may include a hafnium oxide material or an aluminum nitride material. The ferroelectric material may have a structure in which a dopant is injected into a hafnium oxide-based material or a structure in which a dopant is injected into an aluminum nitride-based material. When the ferroelectric material is a hafnium oxide-based material, the dopant may be Zr, La, Al, Si, or Y. When the ferroelectric material is an aluminum nitride-based material, the dopant may be B or Sc.

Alternatively, the ferroelectric material may include a ferroelectric material having, for example, at least one of a fluorite structure, a perovskite structure, or a wurtzite structure.

The ferroelectric material having a fluorite structure may include, for example, HfO₂ or ZrO₂. In this regard, HfO₂ or ZrO₂ may have a crystal structure of tetragonal system or a crystal structure of orthorhombic system. The crystal structure of tetragonal system may have anti-ferroelectricity, and the crystal structure of orthorhombic system may have ferroelectricity. Non-doped HfO₂ may have the stable crystal structure of tetragonal system or may have the crystal structure of orthorhombic system according to the size of crystal grain. Non-doped ZrO₂ may have the stable crystal structure of tetragonal system. Non-doped HfO₂ or ZrO₂ may include nano crystals having a grain size of about 1 nm to about 3 nm, but the disclosure is not limited thereto.

The fluorite-based material may include, for example, HfO₂ or ZrO₂ including a dopant. The dopant may include, for example, at least one of Al, Ga, Co, Ni, Mg, In, La, Y, Nd, Sm, Er, Sr, Ba, Gd, Ge, N or Si. However, this is merely an example. HfO₂ or ZrO₂ including a dopant may have the crystal structure of tetragonal system having anti-ferroelectricity or the crystal structure of orthorhombic system according to the grain size and doping concentration. The smaller the grain size and the higher the doping concentration, the more stable the crystal structure of tetragonal system may be, and the larger the grain size and the smaller the lower the doping concentration, the more stable the crystal structure of orthorhombic system may be.

HfO₂ or ZrO₂ doped with a dopant may include nanocrystals having a greater grain size than the non-doped HfO₂ or ZrO₂. For example, HfO₂ or ZrO₂ doped with a dopant may have a grain size of about 4 nm to about 7 nm or about 4 nm to about 5 nm, but the disclosure is not limited thereto.

The concentration of a dopant may vary depending on a type of the dopant. For example, when the dopant is Si, the doping concentration may be about 1 at % to about 5 at %. However, the disclosure is not limited thereto.

The ferroelectric material having a perovskite structure may include a material having an ABO₃ composition (A and B each represent a metal element). The perovskite-based material may include, for example, at least one of PbZrO₃, PbTiO₃, BaTiO₃, SrTiO₃, or CaTiO₃. However, the disclosure is not limited thereto. The perovskite-based material may have the crystal structure of tetragonal system having anti-ferroelectricity or the crystal structure of orthorhombic system having ferroelectricity according to a composition ratio of elements.

The wurtzite-based material may include non-doped AlN, GaN, or InN or may include AlN, GaN, or InN each including a dopant. The dopant may include at least one of boron (B) or scandium (Sc).

For example, the second charge blocking layer 1290 may include hafnium zirconium oxide (HfZrO), and Zr/(Hf+Zr) may be about 20 at % to about 80 at %.

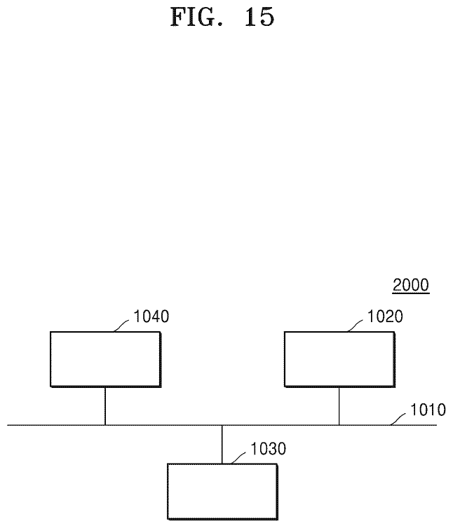

FIG. 15 is a schematic of an electronic device according to at least one embodiment.

Referring to FIG. 15, the electronic device 2000 includes one or more electronic device components, including a processor (e.g., processing circuitry) 1020 and a memory 1030 that are communicatively coupled together via a bus 1010.

The processing circuitry 1020, may be included in, may include, and/or may be implemented by one or more instances of processing circuitry such as hardware including logic circuits, a hardware/software combination such as a processor executing software; or a combination thereof. For example, the processing circuitry 1020 may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc. In some example embodiments, the memory 1030 may include a non-transitory computer readable storage device, for example a solid state drive (SSD), storing a program of instructions, and the processing circuitry 1020 may be configured to execute the program of instructions to implement the functionality of the electronic device 1000.

In some example embodiments, the electronic device 1000 may include one or more additional components 1040, coupled to bus 1010, which may include, for example, a power supply, a light sensor, a light-emitting device, any combination thereof, and/or the like. In some example embodiments, one or more of the processing circuitry 1020, memory 1030, or one or more additional components 1040 may include the boron nitride film of FIG. 1 and/or any of the semiconductor devices according to any of the example embodiments described with reference to, e.g., FIGS. 3-14, and/or the like.

As described above, the boron nitride film according to at least one embodiment may be usefully applied to a dielectric layer, a spacer layer, a diffusion barrier layer, an etch prevention layer, etc. of various electronic devices or semiconductor devices.

The boron nitride film according to at least one embodiment has a relatively low dielectric constant and a relatively high thermal conductivity. Parasitic capacitance between gate electrodes may be reduced by applying the boron nitride film of a small thickness to the gate insulating layer. In addition, the boron nitride film according to at least one embodiment has an excellent thermal conductivity, thereby effectively dissipating heat generated from a semiconductor device employing the boron nitride film.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A boron nitride film comprising:
a boron nitride compound,
wherein the boron nitride film has a dielectric constant within a range of about 2.3 to about 8 at an operating frequency of 100 kHz and has a thermal conductivity within a range of about 1.3 W/mK to about 10 W/mK.

2. The boron nitride film of claim 1, wherein the thermal conductivity is in a range of about 1.7 W/mK to about 5 W/mK.

3. The boron nitride film of claim 1, wherein a ratio of boron to nitrogen in the boron nitride film is in a range of about 1.15 to about 1.5.

4. The boron nitride film of claim 1, wherein the boron nitride film has at least one of an amorphous structure or a nanocrystal structure.

5. The boron nitride film of claim 1, wherein the boron nitride film has a thickness in a range of about 1 nm to about 1 μm.

6. The boron nitride film of claim 1, wherein the boron nitride film has a mass density within a range of about 1 g/cm³ to about 3 g/cm³.

7. The boron nitride film of claim 1, wherein the boron nitride film has a breakdown field of 4 MVcm⁻¹ or more.

8. The boron nitride film of claim 1, wherein the boron nitride film has a roughness in a range of about 0.3 root-mean-square (RMS) to about 0.6 RMS.

9. A semiconductor device comprising:
a conductive wiring;
a dielectric layer surrounding at least a part of the conductive wiring; and
a diffusion barrier layer between the conductive wiring and the dielectric layer and configured to inhibit a conductive material of the conductive wiring from diffusing into the dielectric layer,
wherein at least one of the dielectric layer or the diffusion barrier layer comprises a boron nitride film comprising a boron nitride compound, and
wherein the boron nitride film has a dielectric constant within a range of about 2.3 or more and about 8 or less at an operating frequency of 100 kHz and has a thermal conductivity within a range of about 1.3 W/mK to about 10 W/mK.

10. The semiconductor device of claim 9, wherein the thermal conductivity is in a range of about 1.7 W/mK to about 5 W/mK.

11. The semiconductor device of claim 9, wherein a ratio of boron to nitrogen in the boron nitride film is in a range of about 1.15 to about 1.5.

12. A semiconductor device comprising:
a stack including alternating gate electrodes and boron nitride films; and
a plurality of cell strings in the stack, wherein each of the plurality of cell strings comprises
a channel layer,
a charge tunneling layer on the channel layer,
a charge trap layer on the charge tunneling layer, and
a charge blocking layer on the charge trap layer,
wherein the boron nitride film comprises a boron nitride compound and has a dielectric constant in a range of about 2.3 to about 8 at an operating frequency of 100 kHz and a thermal conductivity in a range of about 1.3 W/mK to about 10 W/mK.

13. The semiconductor device of claim 12, wherein the thermal conductivity is in a range of about 1.7 W/mK to about 5 W/mK.

14. The semiconductor device of claim 12, wherein a ratio of boron to nitrogen in the boron nitride film is in a range of about 1.15 to about 1.5.

15. The semiconductor device of claim 12, wherein the boron nitride film has a mass density within a range of about 1 g/cm³ to about 3 g/cm³.

16. The semiconductor device of claim 12, wherein the boron nitride film has at least one of an amorphous structure or a nanocrystal structure.

17. The semiconductor device of claim 12, wherein the charge blocking layer includes
a first charge blocking layer and a second charge blocking layer, and
wherein the second charge blocking layer includes a fluorite-based material, a perovskite-based material, or a wurtzite-based material.

18. The semiconductor device of claim 17, wherein the fluorite-based material includes at least one of HfO₂ or ZrO₂.
